(19) United States
(12) Patent Application Publication
(10) Pub. No.: US 2011/0133305 A1
(43) Pub. Date: Jun. 9, 2011

(54) SEMICONDUCTOR CHIP FOR SUPPRESSING ELECTROMAGNETIC WAVE

(75) Inventors: Young-Ho KIM, Daejeon (KR); Je-Hoon Yun, Daejeon (KR)

(73) Assignee: ELECTRONICS AND TELECOMMUNICATIONS RESEARCH INSTITUTE, Daejeon (KR)

(21) Appl. No.: 12/953,742

(22) Filed: Nov. 24, 2010

(30) Foreign Application Priority Data
Dec. 4, 2009 (KR) 10-2009-0120019

(51) Int. Cl. H01L 29/02

(52) U.S. Cl. 257/503; 257/E29.002

(57) ABSTRACT

A semiconductor chip includes: a semiconductor substrate having a plurality of electronic elements therein; a metal circuit pattern formed on the semiconductor substrate and allowing the plurality of electronic elements to be electrically connected to one another; and dummy metal patterns formed on the semiconductor substrate and the metal circuit pattern to suppress a predetermined specific frequency ranges.

### CROSS-REFERENCE TO RELATED APPLICATIONS

The present application claims priority of Korean patent application No. 10-2009-0120019, filed on Dec. 4, 2009, which is incorporated herein by reference in its entirety.

### BACKGROUND OF THE INVENTION

1. Field of the Invention

Exemplary embodiments of the present invention relate to a semiconductor chip; and, more particularly, to a semiconductor chip capable of suppressing an electromagnetic wave radiated therefrom or introduced thereinto.

2. Description of Related Art

With the rapid development of electronic industry and information communication technology, multi-functional digital electronic appliances such as computers, cellular phones or PDAs have become a vital part of our everyday lives. Such electronic appliances are conveniently available for our everyday lives, but may cause electromagnetic interference such as communication interference or an abnormal operation of neighbor electric/electronic appliances due to emitted electromagnetic waves. For example, many frequency components are radiated from general electronic appliances using clocks to the free space in the form of electromagnetic waves. Moreover, since a clock speed has been increased for fast signal processing, it is highly probable that a large amount of electromagnetic waves will be radiated to the free space.

Furthermore, with the eye-opening progress of a communication market together with the development of a communication technology, the number of radio communication appliances becoming a vital part of our everyday lives has increased, resulting in the frequent transmission of wireless RF signals. In addition, since a high-gain power amplifier is used for transmitting a radio wave to a long distance, a high power signal travels through the free space. Such radiated electromagnetic waves exert influence on a neighbor board or semiconductor element with a parasitic antenna pattern, thereby causing a serious problem.

In this regard, in the conventional art, a metal box is fabricated to cover a part, where a large amount of electromagnetic waves are generated, or a semiconductor element or a system adversely affected by the electromagnetic waves, thereby solving the problems caused by the electromagnetic waves. However, the use of the metal box causes several problems such as spatial limitation, additional cost, resonance and heat generation.

Meanwhile, in general, 90% or more of semiconductor elements used for electronic appliances such as computers or terminals have been produced through a CMOS process. In other words, most memories, and digital and RF/analog semiconductor elements in electronic appliances are CMOS elements, and only RF elements are compound elements in terms of frequency characteristics. However, with the development of a nano process technology, compound elements have been gradually changed into CMOS elements. It is predicted that all semiconductor elements in electronic appliances will be produced through the CMOS process in a short time. Thus, a technology against electromagnetic susceptibility and electromagnetic radiation in a CMOS element is important more and more.

FIG. 1 is a cross-sectional view of a semiconductor element fabricated through a general CMOS process.

Referring to FIG. 1, a general semiconductor element includes a P type substrate 110 having an N well region, a plurality of oxide layers 120, a plurality of poly layers 130, a plurality of metal layers 141 to 148, and a plurality of via layers 151 to 157. Most electronic elements such as NMOSs, PMOSs, registers, capacitors or diodes are formed around the substrate 110 and the poly layers 130. For electrical connection among the electronic elements, a plurality of metal layers and vias are used. Oxide fills remaining spaces.

The plurality of metal layers are provided for some several reasons such as a complicated and integrated circuit structure and frequency characteristics. In general, five metal layers are used in a 250 nm process, six metal layers are used in a 180 nm process, and eight metal layers are used in a 130 nm process. In terms of a semiconductor design process, the layout of target circuits based on design drawings is performed and then a dummy filling process is performed to additionally fill meaningless metal pieces in a circuit configuration into an empty space. The reason for filling the dummy metals is for electrically protecting poly and metal lines used as a conducting wire. In detail, oxide is grown on a semiconductor substrate and poly or metal layers are stacked on the oxide one by one. Since a stepped portion of the top metal layer is formed between a place where both the poly and metal layer are stacked and a place where only the top metal layer is stacked, the thickness of the metal at the boundary surface is extremely thinned. Therefore, the metal may be cut due to heavy process stress applied thereto. Even if the metal is not cut, the metal may be damaged by heat generated by the resistance of the metal even when a small amount of current flows.

In order to solve such problems, dummy metals including auxiliary poly and metal are filled, so that stepped portions among the metal layers are compensated through the above process. The used dummy metals are generally simple pieces shaped like a brick. In accordance with the conventional dummy filling process, stepped portions among the metal layers are solved by allowing the entire metal density of a chip to be uniform. However, there no special countermeasures against electromagnetic waves.

### SUMMARY OF THE INVENTION

An embodiment of the present invention is directed to provide a semiconductor chip capable of suppressing electromagnetic waves of at least one specific frequency band, which are radiated therefrom, by using a conventional semiconductor fabricating technology.

Another embodiment of the present invention is directed to provide a semiconductor chip capable of blocking harmonic electromagnetic waves introduced from an outside.

In accordance with an embodiment of the present invention, a semiconductor chip includes: a semiconductor substrate having a plurality of electronic elements therein; a metal circuit pattern formed on the semiconductor substrate and allowing the plurality of electronic elements to be electrically connected to one another; and dummy metal patterns formed on the semiconductor substrate and the metal circuit pattern to suppress a predetermined specific frequency ranges.

Furthermore, the dummy metal patterns may include: a plurality of main patterns having a predetermined width; and a plurality of sub-patterns spaced apart from the plurality of main patterns and having a predetermined width, wherein the plurality of main patterns and the plurality of sub-patterns may be repeated on metal layers, respectively.

Furthermore, in the dummy metal patterns, a width of the main patterns, an interval between main patterns adjacent to each other, and a width of the sub-patterns may form pole and zero of the specific frequency component.

Furthermore, the width of the main patterns, the interval between the main patterns adjacent to each other, and the width of the sub-patterns may form pole and zero of high order harmonic frequency components of the specific frequency component.

Furthermore, the dummy metal patterns may include a plurality of main patterns and a plurality of sub-patterns, which form parasitic resistors, parasitic inductors and parasitic capacitors, and the main patterns may be spaced apart from one another. The sub-patterns may be disposed among the main patterns, respectively.

Furthermore, the dummy metal patterns may be formed of a single layer or a plurality of layers.

In addition, the dummy metal patterns may have respectively a pattern for suppressing a specific frequency band in each layer, or have all a single pattern to suppress only one specific frequency band.

Moreover, the dummy metal patterns may be electrically connected to one another through vias to form one dummy metal pattern.

### BRIEF DESCRIPTION OF THE DRAWINGS

FIG. 1 is a cross-sectional view of a semiconductor chip fabricated through a general CMOS process.

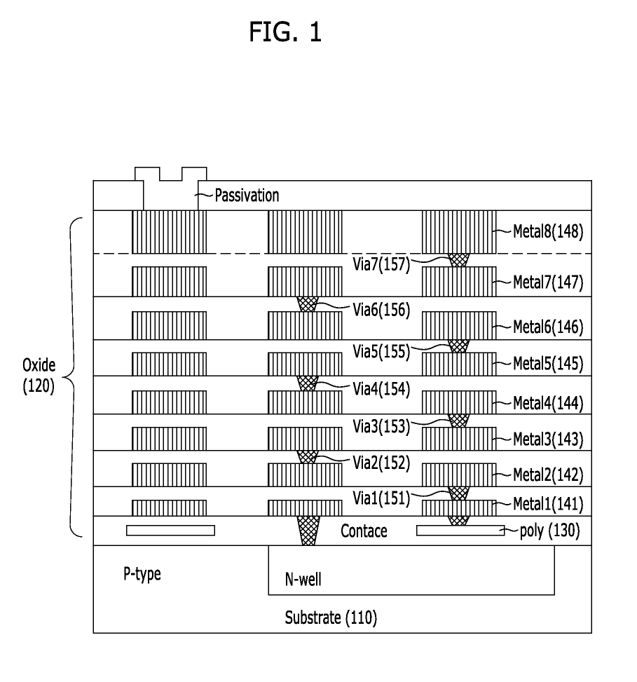

FIG. 2 is a three-dimensional structure diagram of a general semiconductor chip fabricated through a CMOS process.

FIGS. 3A and 3B are diagrams illustrating a semiconductor chip in accordance with one embodiment of the present invention.

FIGS. 4A and 4B are diagrams illustrating a semiconductor chip in accordance with another embodiment of the present invention.

FIG. 5 is a graph illustrating resonant frequency characteristics of a semiconductor chip illustrated in FIGS. 3A and 3B in accordance with one embodiment of the present invention.

### DESCRIPTION OF SPECIFIC EMBODIMENTS

Exemplary embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention. The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

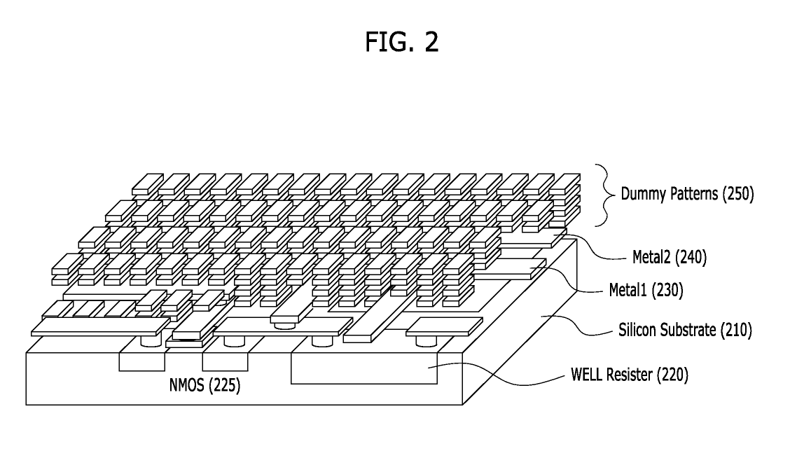

FIG. 2 is a three-dimensional structure diagram of a general semiconductor chip fabricated through a CMOS process.

Referring to FIG. 2, circuit patterns 230 and 240 are formed on a silicon substrate 210. The circuit patterns are predetermined by a circuit designer, and respective elements are connected to a poly layer or a metal layer.

A plurality of hexahedra (rectangular bricks) are stacked on the silicon substrate 210 and the circuit patterns. The plurality of hexahedra are dummy patterns 250 made of poly or metal. As described in the conventional art, the dummy patterns 250 are used for constantly maintaining stepped portions among metals, and a process for forming the dummy patterns 250 is also called a dummy filling process.

Since poly has a conduction slightly lower than that of metal but it can stand comparison with metal, the following description will be given on the assumption that the poly is comprehensively included in a metal layer.

The dummy patterns 250 illustrated in FIG. 2 may suppress electromagnetic waves radiated from the semiconductor chip circuit illustrated in FIG. 2 or introduced from an outside even if the suppressed amount of the electromagnetic waves is small. However, since multiple harmonic frequencies with respect to an operation frequency of a semiconductor chip circuit are mainly radiated, it is very less probable that the electromagnetic waves will be suppressed. Thus, it is necessary to sufficiently analyze an operation frequency spectrum of the semiconductor chip circuit and consider a frequency band to be attenuated. When a spatial filter (FSS) including dummy metal patterns is determined according to such a frequency band, appropriate frequency selection filtering is achieved.

Meanwhile, if the semiconductor chip circuit illustrated in FIG. 2 radiates a small amount of electromagnetic waves therefrom and is sensitive to external electromagnetic waves, it is necessary to design the semiconductor chip circuit according to the suppression of a frequency signal with the largest intensity which is generated around the semiconductor chip.

In this regard, the following description will be given about a semiconductor chip capable of selectively suppressing electromagnetic waves generated therefrom and blocking electromagnetic waves introduced from an outside by adjusting the shape, arrangement, distance, length, size and the like of the dummy patterns 250.

Hereinafter, the semiconductor chip in accordance with one embodiment of the present invention will be described in detail with reference to the accompanying drawings.

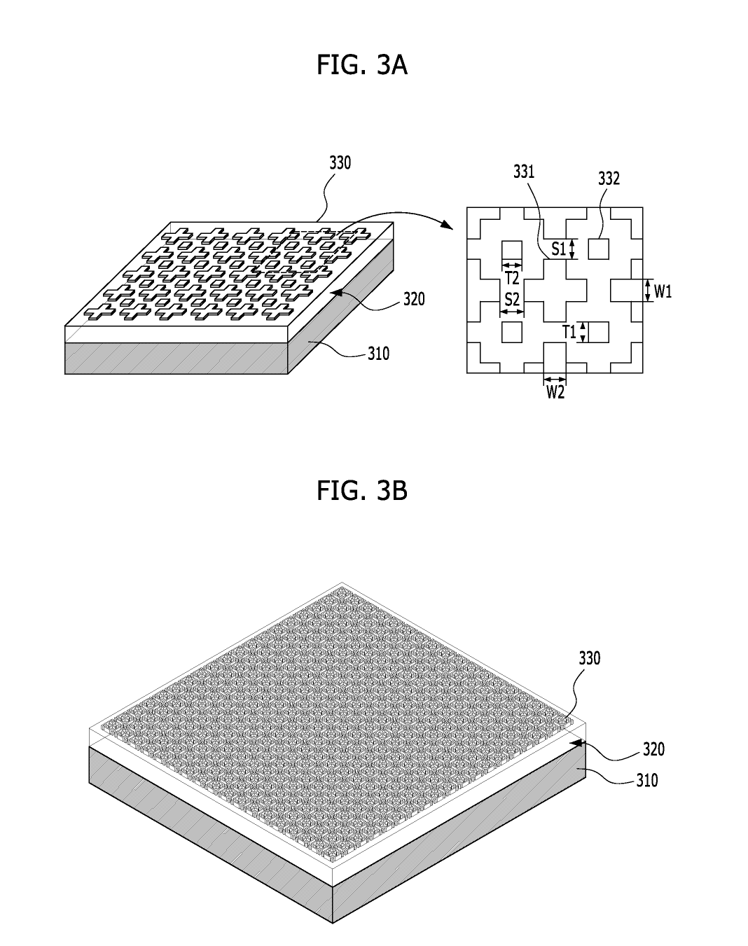

FIGS. 3A and 3B are diagrams illustrating the semiconductor chip in accordance with one embodiment of the present invention, wherein FIG. 3A is a partial perspective view illustrating the semiconductor chip in accordance with one embodiment of the present invention, FIG. 3A is a partially enlarged view illustrating the semiconductor chip in accordance with one embodiment of the present invention, and FIG. 3B is an entire perspective view illustrating the semiconductor chip in accordance with one embodiment of the present invention.

Referring to FIGS. 3A and 3B, a three-dimensional structure of the semiconductor element in accordance with one embodiment of the present invention includes a semiconductor substrate 310, an oxide layer 320, and a dummy metal pattern 330.

The semiconductor substrate 310 may be formed of a silicon substrate and includes a plurality of electronic elements, such as NMOSs and PMOSs, which are disposed thereon. The plurality of disposed electronic elements are predetermined by a designer.

In terms of circuit patterns, circuits designed by a user are disposed. The plurality of metals illustrated in FIG. 2 are disposed according to a design scheme predetermined by a user. Such a metal pattern allows the plurality of electronic elements disposed on the semiconductor substrate 310 to be electrically connected to one another.

The dummy metal pattern 330 is formed of one layer including patterns located on the semiconductor layer 210 of the dummy patterns 250 illustrated in FIG. 2, and serves as a spatial filter that filters a specific frequency band predetermined by a user. The dummy metal pattern 330 may be formed in parallel to the semiconductor substrate 310.

Such a dummy metal pattern 330 may prevent radiation of a specific electromagnetic wave radiated from the semiconductor chip in accordance with one embodiment of the present invention, or block a specific electromagnetic wave introduced from an outside.

More details will be described with reference to FIG. 3B that enlarges a part of the dummy metal pattern 330.

FIG. 3A illustrates one embodiment in which the dummy metal pattern 330 for filtering an electromagnetic wave of a specific frequency band includes main patterns 331 having a cross shape and sub-patterns 332 having a rectangular shape.

The widths (a longitudinal width W1 and a transverse width W2) of each main pattern 331, the intervals (a longitudinal interval S1 and a transverse interval S2) between the main patterns 331, and the widths (a longitudinal width T1 and a transverse width T2) of the sub-patterns 332 form a plurality of parasitic inductors, a plurality of parasitic registers, and a plurality of parasitic capacitors in a circuit configuration. Thus, such main patterns 331 and sub-patterns 332 form poles and zeros on an equivalent model. Consequently, the poles and zeros on the equivalent model are shifted to a specific frequency and a multiple harmonic frequency of an electromagnetic wave, which is generated from the semiconductor chip or introduced from an outside, by adjusting the widths and intervals of the main patterns 331 and the widths of the sub-patterns 332, so that the radiation of the electromagnetic wave or the introduction of the electromagnetic wave may be prevented.

When considering various types of semiconductor chips, it is noted that various types of dummy metal patterns 330 may exist in addition to the type illustrated in FIGS. 3A and 3B, and a plurality of sub-patterns 332 may exist if necessary.

Spatial filtering using such dummy metal patterns 330 is performed, so that frequency characteristics may be confirmed using a 3D EM simulation tool before the fabrication. It is noted that trial and error may occur in order to constitute an accurate spatial filter.

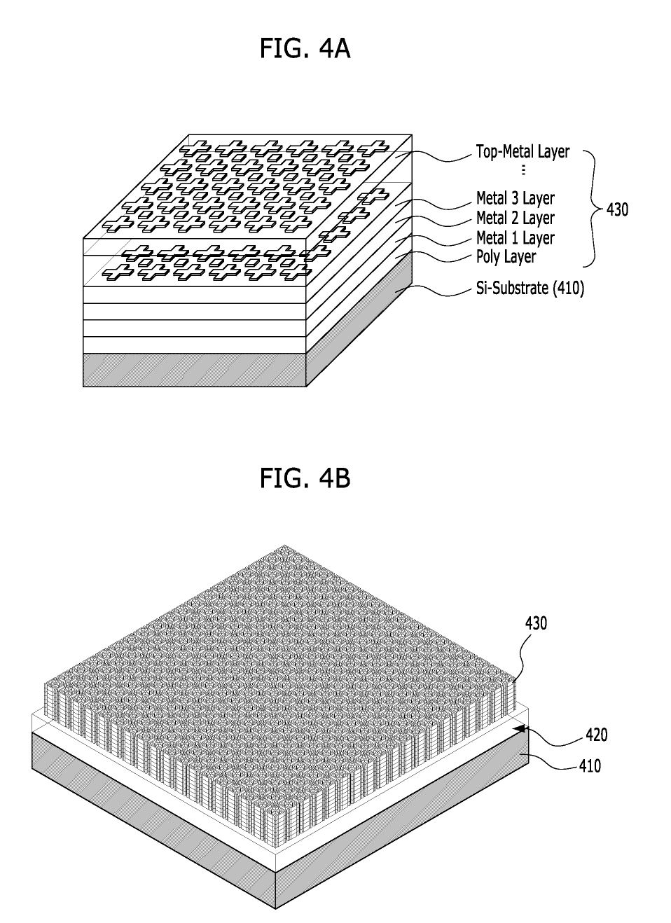

FIGS. 4A and 4B are diagrams illustrating a semiconductor chip using a plurality of metal layers in accordance with another embodiment of the present invention, wherein FIG. 4A is a partial perspective view illustrating the semiconductor chip in accordance with another embodiment of the present invention, and FIG. 4B is an entire perspective view illustrating the semiconductor chip illustrated in FIG. 4A in accordance with another embodiment of the present invention.

Referring to FIGS. 4A and 4B, the semiconductor chip in accordance with another embodiment of the present invention includes a silicon substrate 410 and a plurality of dummy metal patterns 430.

The semiconductor chip illustrated in FIGS. 4A and 4B in accordance with another embodiment of the present invention is obtained by forming the dummy metal pattern 330 illustrated in FIGS. 3A and 3B in a poly layer, a first metal layer, a second metal layer, a third metal layer, . . . , a top metal layer. The dummy metal pattern formed in each layer may be configured to filter only one specific frequency component as illustrated in FIGS. 4A and 4B. The spatial filters formed in the respective layers may also be configured to filter frequency components different from one another. To this end, the patterns of the respective dummy metal patterns 430 are spatially or geometrically arranged in different types.

The dummy metal patterns 430 are obtained by stacking the dummy metal patterns 330 illustrated in FIGS. 3A and 3B.

If the dummy metal pattern 330 in the semiconductor chip illustrated in FIGS. 3A and 3B in accordance with one embodiment of the present invention is a spatial filter of a single frequency band, the semiconductor chip illustrated in FIGS. 4A and 4B in accordance with another embodiment of the present invention may expand a frequency selection bandwidth to a wide range by using the multi-layered dummy metal patterns 430. Using the respective dummy metal patterns 430, a frequency band may be further expanded through overlapping of frequency spectrums or suppression characteristics at a specific frequency band may be maximized. If necessary, it is necessary to adjust the shape (a width of metal and an interval between metals) in consideration of a process design rule. The height of a metal layer is also an important variable value of a design parameter. If necessary, in order to increase the thickness of a metal layer, it may also be possible to form a double layer obtained by connecting two metal layers formed with vias to each other.

Meanwhile, in order to simply filter only a specific frequency band, the dummy metal patterns illustrated in FIG. 2 may be used, and only a specific layer may also be used as a spatial filter employing an arbitrary pattern.

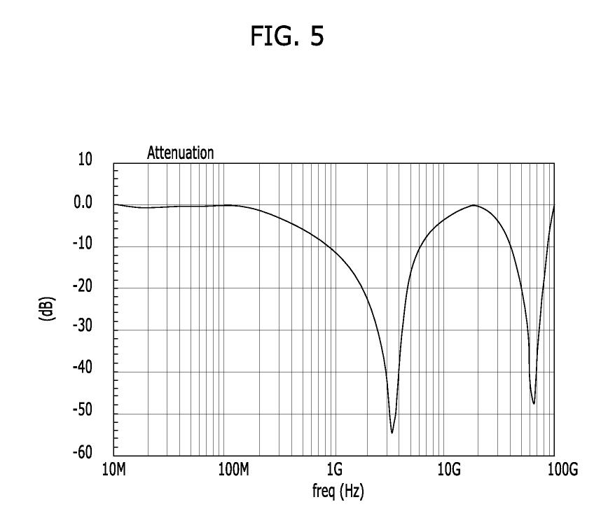

FIG. 5 is a graph illustrating resonant frequency characteristics of the dummy metal pattern 330 in the semiconductor chip illustrated in FIGS. 3A and 3B in accordance with one embodiment of the present invention.

The geometrical parameters of the single dummy metal pattern 330 were adjusted such that signal radiation of a WCDMA frequency band may be suppressed, thereby preventing the influence to an external appliance using the same frequency, and the influence to a semiconductor chip when an external appliance receives signals of the frequency band.

Meanwhile, the semiconductor chip illustrated in FIGS. 4A and 4B in accordance with another embodiment of the present invention has a structure in which a plurality of frequency selection layers are stacked, thereby suppressing frequency signals of various bands. Consequently, the embodiments of the present invention are advantageous for electromagnetic suppression of a semiconductor chip operating with a fast clock or a semiconductor chip which is sensitive to external electromagnetic signals.

Using a semiconductor chip in accordance with the embodiments of the present invention, so that electromagnetic waves radiated therefrom may be effectively suppressed.

Furthermore, electromagnetic waves introduced from an outside may be effectively blocked.

While the present invention has been described with respect to the specific embodiments, it will be apparent to those skilled in the art that various changes and modifications may be made without departing from the spirit and scope of the invention as defined in the following claims.

What is claimed is:

1. A semiconductor chip comprising:
a semiconductor substrate having a plurality of electronic elements therein;
a metal circuit pattern formed on the semiconductor substrate and allowing the plurality of electronic elements to be electrically connected to one another; and
dummy metal patterns formed on the semiconductor substrate and the metal circuit pattern to suppress a predetermined specific frequency ranges.

2. The semiconductor chip of claim 1, wherein the dummy metal patterns comprise:
a plurality of main patterns having a predetermined width; and
a plurality of sub-patterns spaced apart from the plurality of main patterns and having a predetermined width,
wherein the plurality of main patterns and the plurality of sub-patterns are repeated on metal layers, respectively.

3. The semiconductor chip of claim 2, wherein, in the dummy metal patterns, a width of the main patterns, an interval between main patterns adjacent to each other, and a width of the sub-patterns form pole and zero of the specific frequency component.

4. The semiconductor chip of claim 3, wherein the width of the main patterns, the interval between the main patterns adjacent to each other, and the width of the sub-patterns form pole and zero of high order harmonic frequency components of the specific frequency component.

5. The semiconductor chip of claim 1, wherein the dummy metal patterns include a plurality of main patterns and a plurality of sub-patterns, which form parasitic resistors, parasitic inductors and parasitic capacitors, the main patterns are spaced apart from one another, and the sub-patterns are disposed among the main patterns, respectively.

6. The semiconductor chip of claim 1, wherein the dummy metal patterns are formed of a single layer or a plurality of layers.

7. The semiconductor chip of claim 1, wherein the dummy metal patterns have respectively a pattern for suppressing a specific frequency band in each layer, or have all a single pattern to suppress only one specific frequency band.

8. The semiconductor chip of claim 1, wherein the dummy metal patterns are electrically connected to one another through vias to form one dummy metal pattern.
